(19) United States
(12) Patent Application Publication
(10) Pub. No.: US 2020/0313122 A1
(43) Pub. Date: Oct. 1, 2020

(54) EVAPORATION CHAMBER STRUCTURE AND SHUTTER STRUCTURE

(71) Applicant: Wuhan China Star Optoelectronics Semiconductor Display Technology Co., Ltd., Wuhan (CN)

(72) Inventor: Chao XU, Shenzhen (CN)

(73) Assignee: Wuhan China Star Optoelectronics Semiconductor Display Technology Co., Ltd., Wuhan (CN)

(21) Appl. No.: 16/630,437

(22) PCT Filed: Mar. 18, 2019
(86) PCT No.: PCT/CN2019/078518

§ 371 Date: Jan. 12, 2020

(30) Foreign Application Priority Data
Dec. 5, 2018 (CN) 201811479218.4

(51) Int. Cl. H01L 51/56; C23C 14/24; H01L 51/00

(52) U.S. Cl. CPC H01L 51/56; H01L 51/001; C23C 14/24

(57) ABSTRACT

The evaporation chamber structure includes a chamber, a material nozzle, and a shutter structure. The material nozzle locates at a bottom of the chamber for spraying desired-evaporated materials to the substrate to be evaporated. The shutter structure includes a support, a plurality of supporting bars, and a plurality of sub-shutters. The supporting bars are connected to the support. The sub-shutters are disposed between the supporting bars. The sub-shutters are closed and overlapped, or are unfolded through the supporting bars. Sinking of the shutter and leaking of the materials resulted from overweight of the shutter in an evaporation machine is improved by utilized the evaporation chamber structure of the present disclosure which shares the weight of the shutter on the plurality of sub-shutters.

### FIELD OF INVENTION

The present disclosure relates to a field of evaporation, particularly to a field of evaporation of organic light-emitting materials.

### BACKGROUND OF INVENTION

Organic light-emitting diode (OLED) displays have become an attractive developing display technology due to advantages, such as high brightens, quick response times, low power consumption, flexibility, etc. In comparison with thin film transistor (TFT) displays, OLED displays are more suitable for manufacturing larger, thinner, flexible, transparent, double-side displays.

The present technology for manufacturing OLED displays is evaporating an organic material layer on a substrate. The organic materials, which are molecules, are disposed on the substrate by an evaporation machine. Please refer to FIG. 1. The evaporation machine includes an evaporating chamber 10 which can contain a substrate to be evaporated. When evaporating materials sprayed from a nozzle under the substrate, the evaporating materials are unevenly disposed on the substrate 14 because the opening of the nozzle 12 is too narrow. Therefore, a shutter 100 is required to be disposed between the nozzle 12 and the substrate 14. The present shutter 100 includes a main shutter 102, a sub-shutter 104, and a support 106. When the nozzle starts to spray the organic materials, the main shutter 102 and the sub-shutter 104 are closed to make the organic materials diffuse under the shutter 100. When a concentration of the organic materials reaches a predetermined concentration, the main shutter 102 and the sub-shutter 104 are separated from each other to make the organic materials be evenly evaporated on the substrate 14.

### TECHNICAL PROBLEMS

However, in manufacture of large-side panels, the larger diameter of the evaporating chamber is, the larger the size of the shutter is required. Please refer to FIG. 2. The evaporating chamber 20 includes a shutter disposed between a nozzle 22 and a substrate 24. The shutter includes a main shutter 202, a sub-shutter 204, and a support 206. There is only one pivot between the shutter 200 and the support 206. As a result, the weight of the main shutter 202 makes itself sink due the large dimension of the shutter 200. The main shutter 202 is unable to close entirely with the sub-shutters 204 so that the organic materials leak toward to the substrate 24 which affect the quality of the panels.

Therefore, a shutter structure in an evaporation machine is required to solve problems of the sinking of the main-shutter cause from the insufficient supporting force between the support and the shutter during the manufacturing process processes of large-size panels.

### SUMMARY OF INVENTION

The object of the present disclosure is providing an evaporation chamber structure including a chamber, a material nozzle, and a shutter structure. The material nozzle locates at a bottom of the chamber for spraying desired-evaporated materials to the substrate to be evaporated. The shutter structure includes a support, a plurality of supporting bars, and a plurality of sub-shutters. The supporting bars are connected to the support. The sub-shutters are disposed between the supporting bars. The sub-shutters are closed and overlapped, or are unfolded through the supporting bars. A concentration of the desired-evaporated materials is controlled by the plurality of sub-shutters that are closed and overlapped or that are unfolded by the plurality of sub-shutters. A shape of each of the sub-shutters is a fan or a triangle when the sub-shutters are unfolded

The present disclosure further provides an evaporation chamber structure including a chamber, a material nozzle, and a shutter structure. The material nozzle locates at a bottom of the chamber for spraying desired-evaporated materials to the substrate to be evaporated. The shutter structure includes a support, a plurality of supporting bars, and a plurality of sub-shutters. The supporting bars are connected to the support. The sub-shutters are disposed between the supporting bars. The sub-shutters are closed and overlapped, or are unfolded through the supporting bars.

Preferably, a shape of each of the sub-shutters is a fan when the sub-shutters are unfolded.

Preferably, a shape of each of the sub-shutters is a triangle when the sub-shutters are unfolded.

Preferably, center angles of the sub-shutters are the same when the sub-shutters are unfolded.

Preferably, the plurality of sub-shutters can be closed and overlapped, or can be unfolded. A concentration of the desired-evaporated materials is controlled by the plurality of sub-shutters that are closed and overlapped or by the plurality of sub-shutters that are unfolded.

Preferably, the plurality of sub-shutters can be closed and overlapped, or can be unfolded. The concentration of the desired-evaporated materials is controlled by the plurality of sub-shutters that are closed and overlapped or by the plurality of sub-shutters that are unfolded. When the concentration of the desired-evaporated materials meets a predetermined threshold, the sub-shutters view the support as a center to be close and overlapped for evaporating the desired-evaporated materials to the substrate to be evaporated. When the concentration of the desired-evaporated materials does not meet a predetermined threshold, the sub-shutters view the support as a center to be unfolded for avoiding the desired-evaporated materials evaporating to the substrate to be evaporated.

The present disclosure further provides a shutter structure including a support, a plurality of supporting bars, and a plurality of sub-shutters. The supporting bars are connected to the support. The sub-shutters are disposed between the supporting bars. The sub-shutters are closed and overlapped, or are unfolded through the supporting bars.

Preferably, a shape of each of the sub-shutters is fan when the sub-shutters are unfolded.

Preferably, a shape of each of the sub-shutters is triangle when the sub-shutters are unfolded.

Preferably, center angles of each of the sub-shutters are the same when the sub-shutters are unfolded.

### BENEFICIAL EFFECTS

The advantage of the present disclosure is the weight of the shutter is shared by the plurality of sub-shutters which is support by plurality of supporting bars. Hence, sinking of the shutter and leaking of the materials resulted from overweight is improved during the manufacturing processes of large-size panel.

### DESCRIPTION OF DRAWINGS

FIG. 1 illustrates a structure of an evaporating chamber of a present technology.

FIG. 2 illustrates a sinking structure of a main shutter of the present technology.

FIG. 3 illustrates an evaporation chamber structure of a first embodiment of the present disclosure.

FIG. 4 illustrates a lateral view of an overlapped shutter of the first embodiment.

FIG. 5 illustrates an evaporation chamber structure of a second embodiment of the present disclosure.

FIG. 6 illustrates a lateral view of an overlapped shutter of the second embodiment.

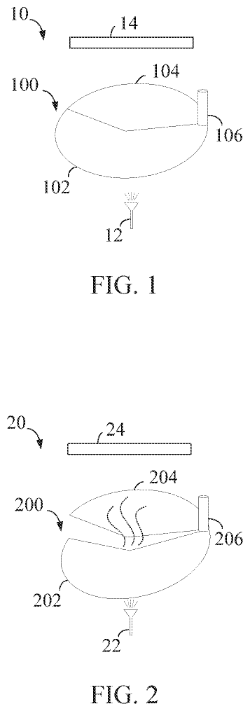

### DETAILED DESCRIPTION OF PREFERRED EMBODIMENTS

Embodiments of the present disclosure will be described in detail accompanying drawings. The longitudinal, latitudinal, upper, lower, left, right, front, rear are merely for convenience of describing the relative relationship between the components rather than limitations of the embodiments of the present disclosure. It is obvious that the described embodiments are only a part, not all, of the embodiments of the invention. All other embodiments obtained by a person of ordinary skill in the art based on the embodiments of the present disclosure without creative efforts are within the scope of the present disclosure.

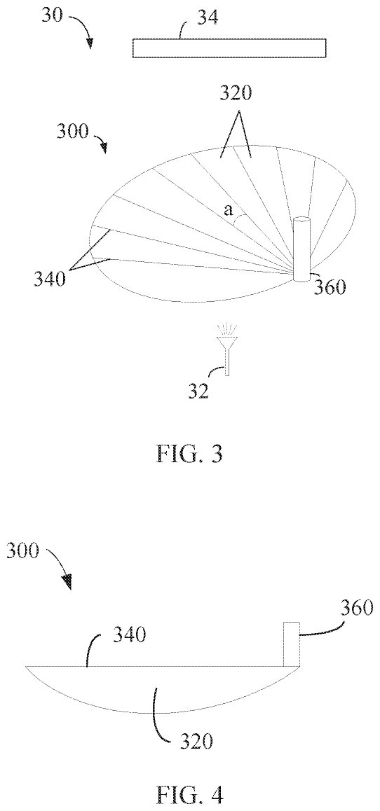

Please refer to FIG. 3 which illustrates an evaporation chamber structure of a first embodiment of the present disclosure. An evaporating chamber 30 includes a nozzle 32, a substrate 34, and a shutter structure 300 disposed between the nozzle 32 and the substrate 34. The shutter structure 300 includes a plurality of sub-shutters 320, a plurality of supporting bars 340, and support 360. An area required to be covered by the shutter 300 consisting of plurality of sub-shutters 320. A shape of each of the sub-shutters 320 is a fan. All of the sub-shutters 320 form the shutter 300 in a round shape. However, the shapes of the shutter 300 and the sub-shutter 320 are only examples which are not intended to limit the present disclosure. Shutter 300 and sub-shutters 320 in any shapes, dimensions, or structures which fit the cross-section of the evaporating chamber 30 and which can block the diffusion of evaporation materials fall in the protected scope of the present disclosure.

The shutter 300 consists of the plurality of sub-shutters 320. There is supporting bars 340 between the sub-shutters 320. The supporting bar 340 is utilized to support the weight of the sub-shutter 320 and connect to a support 360. Each of the supporting bar 340 has one end connected with support 360. As a result, the weight of the shutter 300 is shared by the plurality of sub-shutters 320. The plurality of supporting bars 340 cooperatively shares the weight of the shutter 300 so that burden of each of the supporting bars becomes lighter. By utilizing the present disclosure, sinking of the main shutter and material leaking resulted from overweight of the shutter, which includes one main shutter and one sub-shutter, can be improved during the manufacturing processes of large-size panels.

Please refer to FIG. 3 and FIG. 4. FIG. 4 illustrates a lateral view of overlapped shutter 300 of the first embodiment (as shown in FIG. 3). Please refer to FIG. 4. After the shutter 300 is closed, each of the sub-shutters 320 are closed and overlapped so that the cross-section shape of the shutter 300 becomes stick which is as narrow as the supporting bars 340. Thus, organic materials pass through the shutter 300 and are evaporated on the substrate 34. Before the concentration of the organic materials reaches a predetermined threshold, the shutter unfolds as shown in FIG. 3 to avoid the organic materials diffusing to the substrate. As a result, quality of the display panels are prevented from being affected by the organic materials which have not reached desired concentration. Preferably, each of the sub-shutters 320 has the same center angle a. Each unfolding and closing angles of the supporting bars 340 is easier to be controlled. The control of unfolding and closing of the shutter 300 is simplified as well.

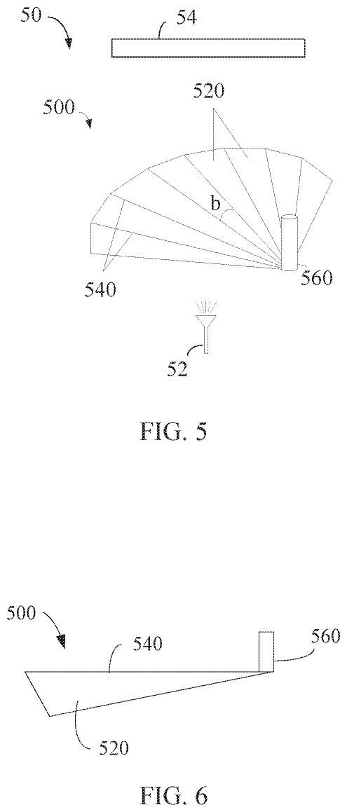

Please refer to FIG. 5 which illustrates an evaporation chamber structure of a second embodiment of the present disclosure. The evaporating chamber 50 of the second embodiment also includes a nozzle 52, a substrate 54, and a shutter 500 as shown in FIG. 5. The shutter 500 includes a plurality of sub-shutters 520, a plurality of supporting bars 540 and a support 560. The shutter 500 also consists of the plurality of sub-shutters 520. There are supporting bars 540 between sub-shutters 520. Each of the supporting bars 540 has one end connected with the support 560 to support the weights of the sub-shutters 520. In the second embodiments, a shape of the sub-shutter 520 is a triangle. In comparison with a fan, a triangle has simpler structure, dimension, and manufacturing process because non-straight parameters such as curve and radian, which are more complex, do not exist in triangles. Preferably, each of the sub-shutters 520 has the same center angle b. Each unfolding and closing angles of the supporting bars is easier to be controlled. The control of unfolding and closing of the shutter 500 is simplified as well.

Please refer to FIG. 6 which illustrates a lateral view of overlapped shutter of the second. Before the concentration of the organic materials sprayed by the nozzle 52 reaches a predetermined threshold, the shutter 500 unfolds to avoid the organic materials diffusing to the substrate.

When concentration of the organic materials sprayed by the nozzle 52 reaches a predetermined threshold, the shutter 540 are closed and overlapped by controlling the supporting bars 540. The cross-section shape of the shutter 500 becomes as narrow as the supporting bars 540. Thus, organic materials pass through the shutter 500 and are evaporated on the substrate 54.

The above description is only a preferred embodiment of the present disclosure. It should be noted that a skilled person in the art can also make improvements and modifications without departing from the principles of the present disclosure. These improvements and modifications fall in the protected scope of the present invention.

What is claimed is:

1. An evaporation chamber structure, applied on a substrate to be evaporated, comprising:
a chamber;
a material nozzle locating at a bottom of the chamber for spraying desired-evaporated materials to the substrate to be evaporated; and
a shutter structure, comprising:
a support;
a plurality of supporting bars connected to the support; and
a plurality of sub-shutters disposed between the supporting bars;
wherein the plurality of sub-shutters are closed and overlapped, or are unfolded through the supporting bars; a concentration of the desired-evaporated materials is controlled by the plurality of sub-shutters that are closed and overlapped or that are unfolded by the plurality of sub-shutters;
wherein a shape of each of the sub-shutters is a fan or a triangle when the plurality of sub-shutters are unfolded.

2. An evaporation chamber structure, applied on a substrate to be evaporated, comprising:
a chamber;
a material nozzle locating at a bottom of the chamber for spraying desired-evaporated materials to the substrate to be evaporated; and
a shutter structure, comprising:
a support;
a plurality of supporting bars connected to the support; and
a plurality of sub-shutters disposed between the supporting bars;
wherein the plurality of sub-shutters are closed and overlapped or are unfolded through the supporting bars.

3. The evaporation chamber structure according to claim 2, wherein a shape of each of the sub-shutters is a fan when the sub-shutters are unfolded.

4. The evaporation chamber structure according to claim 2, wherein a shape of each of the sub-shutters is a triangle when the sub-shutters are unfolded.

5. The evaporation chamber structure according to claim 2, wherein center angles of the sub-shutters are the same when the sub-shutters are unfolded.

6. The evaporation chamber structure according to claim 2, wherein the plurality of sub-shutters can be closed and overlapped, or can be unfolded, and a concentration of the desired-evaporated materials is controlled by the plurality of sub-shutters that are closed and overlapped or by the plurality of sub-shutters that are unfolded.

7. The evaporation chamber structure according to claim 6, wherein the plurality of sub-shutters can be closed and overlapped, or can be unfolded, the concentration of the desired-evaporated materials is controlled by the plurality of sub-shutters that are closed and overlapped or by the plurality of sub-shutters that are unfolded, when the concentration of the desired-evaporated materials meets a predetermined threshold, the sub-shutters view the support as a center to be close and overlapped for evaporating the desired-evaporated materials to the substrate to be evaporated, when the concentration of the desired-evaporated materials does not meet a predetermined threshold, the sub-shutters view the support as a center to be unfolded for avoiding the desired-evaporated materials evaporating to the substrate to be evaporated.

8. A shutter structure, comprising:
a support;
a plurality of supporting bars connected to the support; and
a plurality of sub-shutters disposed between the supporting bars;
wherein the sub-shutters are closed and overlapped, or are unfolded through the supporting bars.

9. The shutter structure according to claim 8, wherein a shape of each of the sub-shutters is fan when the sub-shutters are unfolded.

10. The shutter structure according to claim 8, wherein a shape of each of the sub-shutters is triangle when the sub-shutters are unfolded.

11. The shutter structure according to claim 8, wherein center angles of each of the sub-shutters are the same when the sub-shutters are unfolded.
